(19) United States
(12) Patent Application Publication
(10) Pub. No.: US 2015/0303314 A1
(43) Pub. Date: Oct. 22, 2015

(54) Reflective Type Display Device Including Multifunctional Electrode and Method of Manufacturing the Same

(71) Applicant: Hydis Technologies Co., Ltd., Icheon-si (KR)

(72) Inventor: Seong Jung Yun, Hwaseong-si (KR)

(21) Appl. No.: 14/608,221

(22) Filed: Jan. 29, 2015

(30) Foreign Application Priority Data
Apr. 17, 2014 (KR) 10-2014-0046037

(51) Int. Cl. H01L 29/786; H01L 23/528; H01L 23/532; H01L 21/3205; H01L 29/66; H01L 21/283; H01L 21/31; H01L 21/311; H01L 27/12; H01L 23/31

(52) U.S. Cl. CPC H01L 29/78609; H01L 27/124; H01L 27/1248; H01L 23/528; H01L 23/53261; H01L 23/3171; H01L 29/66742; H01L 21/283; H01L 21/31; H01L 21/31111; H01L 21/32051; H01L 27/1259

(57) ABSTRACT

A reflective type display device may include: in each of the unit pixel regions of a lower substrate, a gate electrode connected to a gate line; a first insulating layer formed on the gate electrode; a semiconductor layer planarly overlapped with the gate electrode, with the first insulating layer interposed therebetween; a source electrode having one side connected to a data line and the other side formed to be overlapped with a portion of the semiconductor layer; a second insulating layer formed on the semiconductor layer and the source electrode; a contact hole formed by removing a portion of the second insulating layer so as to expose a partial region of the semiconductor layer; and a multifunction electrode formed on an upper portion of the second insulating layer and directly connected to the semiconductor layer through the contact hole.

### CROSS-REFERENCE TO RELATED APPLICATION

This application claims the benefit of priority under 35 U.S.C. §119(a) of Korean Patent Application No. 10-2014-0046037, filed on Apr. 17, 2014, with the Korean Intellectual Property Office, the entire disclosure of which is incorporated herein by reference for all purposes.

### FIELD

The present invention relates to a reflective type display device and more particularly to, a reflective type display device including a multifunction electrode.

### BACKGROUND

Since reflective type display devices such as electronic paper display devices do not use a backlight unit, a degree of power consumption may be relatively low and a degree of portability may be high, such that demand for the reflective type display devices has been gradually increasing.

Such a reflective type display device may be configured to include gate lines (G) and data lines (D) defining unit pixel areas, a switching element such as a thin film transistor (TFT) positioned within each unit pixel area, a lower substrate provided with a pixel electrode (please refer to FIG. 1), and an upper substrate (not shown) provided with a common electrode.

In such a reflective type display device, an area ratio of a pixel electrode in the unit pixel area needs to be increased in order to increase a fill-factor having a similar concept to that of an aperture rate of a liquid crystal display.

However, in the case that the pixel electrode is formed on an upper portion of the TFT in the reflective type display device having a bottom gate structure in which a gate is disposed below a semiconductor layer, a back-channel is formed by the pixel electrode, thereby causing a leakage current.

In order to solve such a defect, a thick organic insulating layer having a relatively low dielectric constant may be formed between the semiconductor layer and the pixel electrode. However, even in the case, the possibility of causing a current leakage due to the back-channel may still remain.

Thus, as illustrated in FIG. 2, in order to implement TFT characteristics, it may be advantageous not to form a pixel electrode 9 on an upper portion of the TFT. However, in the case that the pixel electrode is not formed an upper portion of the TFT, a reduction in fill-factor may be caused.

In addition, the TFT may be activated by external light incident onto the upper portion of the TFT in which the pixel electrode is not formed, thereby incurring a leakage current. In order to prevent the leakage current, a light shielding film 7 may be formed on the upper portion of the TFT. However, in order to form such a light shielding film, a mask process for manufacturing a reflective type display device may be additionally provided to result in an increase in manufacturing costs.

### RELATED ART DOCUMENT

(Patent Document) Korean Patent Laid-Open Publication No. 10-2013-0062792

### SUMMARY

Therefore, an aspect of exemplary embodiments of the present invention is to provide a reflective type display device including a multifunctional electrode serving as a drain, a pixel electrode, and a light shielding layer.

Another aspect of exemplary embodiments of the present invention is to provide a reflective type display device having an improved fill factor due to the expansion of a pixel electrode.

Another aspect of exemplary embodiments of the present invention is to provide a reflective type display device in which a leakage current due to a pixel electrode positioned on an upper portion of a thin film transistor (TFT) is not generated.

Another aspect of exemplary embodiments of the present invention is to provide a reflective type display device allowing for the simplification of a manufacturing process and a significant reduction in a manufacturing cost thereof.

The above and other purposes of exemplary embodiments of the present disclosure may be achieved by a reflective type display device including a multifunctional electrode and a manufacturing method thereof. According to an embodiment of the present invention, there is provided a reflective type display device having a lower substrate on which a plurality of gate lines and a plurality of data lines are arranged to intersect each other in order to form a plurality of unit pixel regions and an upper substrate on which a common electrode is formed, the reflective type display device including: in each of the unit pixel regions of the lower substrate, a gate electrode connected to one of the gate lines; a first insulating layer formed on an entire surface of the lower substrate on which the gate lines and the gate electrode are formed; a semiconductor layer planarly overlapped with the gate electrode, with the first insulating layer being interposed therebetween; a source electrode having one side connected to one of the data lines and the other side formed to be overlapped with a portion of the semiconductor layer; a second insulating layer formed on the entire surface of the lower substrate on which the semiconductor layer and the source electrode are formed; a contact hole formed by removing a portion of the second insulating layer so as to expose a partial region of the semiconductor layer; and a multifunction electrode formed on the second insulating layer and directly connected to the semiconductor layer through the contact hole.

According to another embodiment of the present invention, there is provided a method of manufacturing a reflective type display device having a lower substrate on which a plurality of gate lines and a plurality of data lines are arranged to intersect each other in order to form a plurality of unit pixel regions and an upper substrate on which a common electrode is formed, the method including: forming the gate lines and a gate electrode on the lower substrate; forming a first insulating layer on the lower substrate on which the gate lines and the gate electrode are formed; forming a semiconductor layer, the data lines, and a source electrode on the first insulating layer, the semiconductor layer being planarly overlapped with the gate electrode, and the source electrode being connected to one of the data lines and being partially overlapped with the semiconductor layer; forming a second insulating layer including a contact hole so as to expose a partial region of the semiconductor layer on the upper portion of the lower substrate on which the semiconductor layer, the data lines, and the source electrode are formed; and forming a multifunction electrode on an upper portion of the second insulating layer to be directly connected to the semiconductor layer through the contact hole.

The multifunction electrode may be formed to cover the entirety of an upper portion of the semiconductor layer.

The other side of the source electrode may be positioned between the first insulating layer and the semiconductor layer. The other side of the source electrode may be positioned between the semiconductor layer and the second insulating layer.

The multifunction electrode may be formed of a corrosion resistant alloy. The corrosion resistant alloy may be a molybdenum alloy or a titanium alloy. The reflective type display device may further include a passivation layer disposed below the second insulating layer.

### BRIEF DESCRIPTION OF THE DRAWINGS

FIG. 1 is a plan view of a lower substrate of a conventional reflective type display device;

FIG. 2 is a cross-sectional view of FIG. 1, taken along line I-I′;

FIG. 3 is a plan view of a lower substrate of a reflective type display device according to an exemplary embodiment of the present invention;

FIG. 4 is a cross-sectional view of FIG. 3, taken along line II-II′; and

FIG. 5 is a cross-sectional view of a lower substrate in a reflective type display device according to another exemplary embodiment of the present invention.

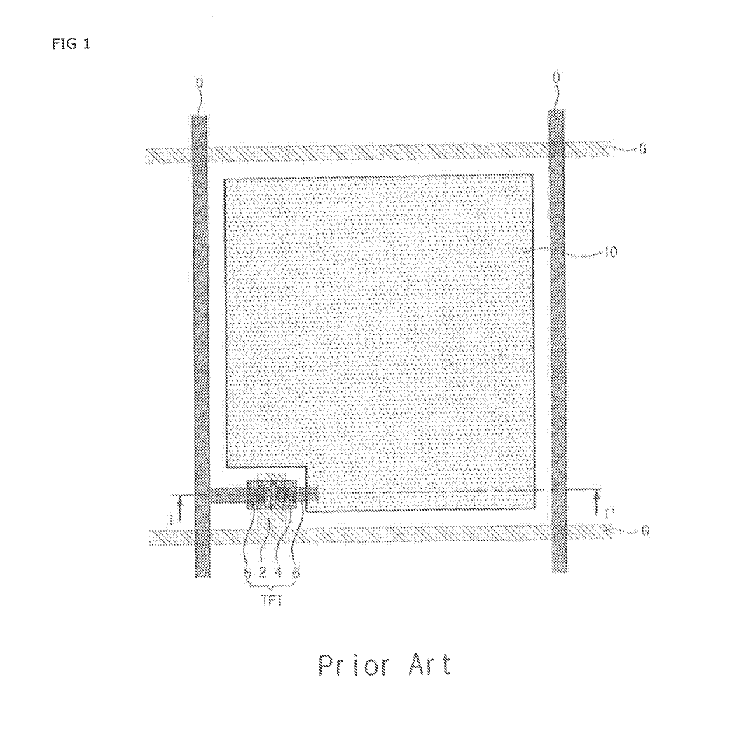

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

Hereinafter, a reflective type display device including a multifunctional electrode and a manufacturing method thereof will be described in detail with reference to the attached drawings.

In general, a reflective type display device may have a lower substrate on which a plurality of gate lines and a plurality of data lines are arranged to intersect each other in order to form a plurality of unit pixel regions and an upper substrate on which a common electrode is formed.

A reflective type display device according to an exemplary embodiment of the present invention may be characterized by having a multifunctional electrode formed on a lower substrate thereof, and other portions of the device except for the lower substrate, may be identical to those of a reflective type display device according to the related art. Thus, in the following description, only the lower substrate required to understand the reflective type display device according to the exemplary embodiment is explained, and a description of the other portions will be omitted so as not to hider the gist of the present invention.

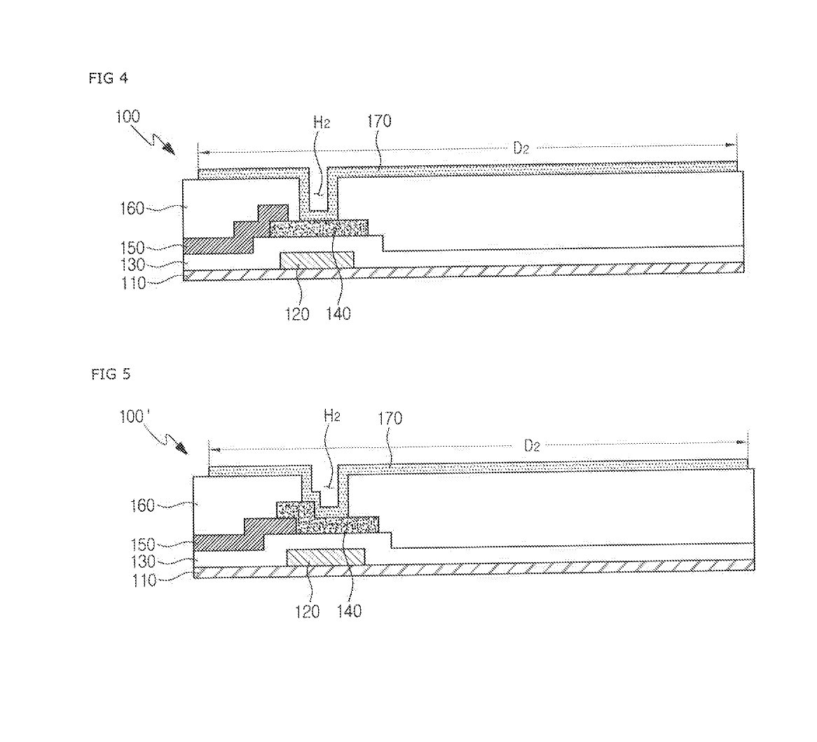

FIGS. 3 and 4 are a plan view and a cross-sectional view of a lower substrate 100 of a reflective type display device according to an exemplary embodiment of the present invention.

A thin film transistor (TFT) may be formed in an intersection region of gate lines G and data lines D on the lower substrate of the reflective type display device according to an exemplary embodiment of the present invention.

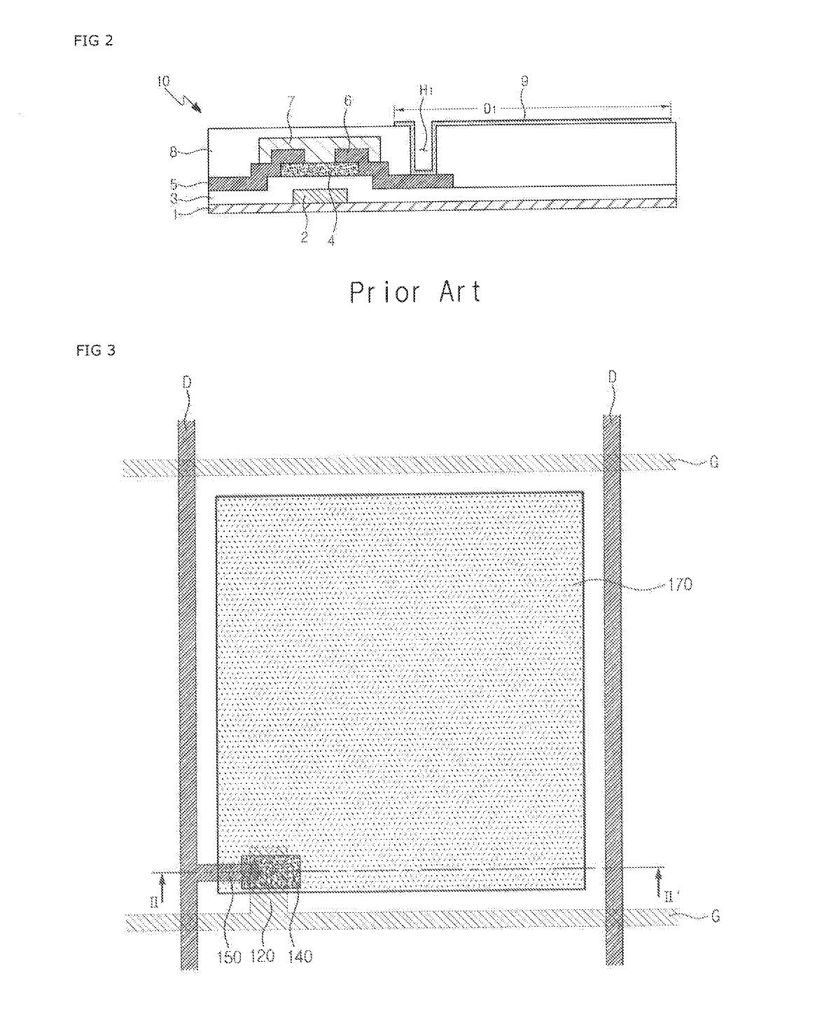

However, unlike the TFT of the reflective type display device according to the related art illustrated in FIG. 2, a drain electrode is not formed and a multifunctional electrode 170 may be directly connected to a semiconductor layer 140 through a contact hole H2.

Through such a structure of the present invention, in the reflective type display device according to an exemplary embodiment of the present invention, a leakage current due to a back-channel may not occur even in the case that the multifunctional electrode 170 is formed on an upper portion of the semiconductor layer. Thus, the multifunctional electrode may be formed as large as possible within a unit pixel area, whereby a fill-factor may be improved.

More specifically, the TFT of the reflective type display device according to the related art may include three electrodes such as a gate electrode 2, a source electrode 5 and a drain electrode 6 as illustrated in FIG. 2, and the pixel electrode 9 may be connected to the drain electrode through a contact hole H1.

Thus, when a gate signal is input to the gate electrode 2, a semiconductor layer 4 may be activated, such that a data signal may be supplied to the pixel electrode 9 through the drain electrode 6 from the source electrode 5 connected to the data line D.

Thereafter, in the case that the gate signal is not present, the semiconductor layer 4 may be in an open state. However, since the pixel electrode 9 is already charged with a voltage of the data signal, an electric field may be formed between the pixel electrode and the semiconductor layer in the case that the pixel electrode is formed on the upper portion of the semiconductor layer. Thus, the semiconductor layer may be activated due to the consequently formed electric field to thereby cause a defect in which a current charged in the pixel electrode is leaked.

On the other hand, according to the exemplary embodiment of the present invention, the multifunction electrode 170 may be directly connected to the semiconductor layer through the contact hole H2. Thus, an electric field may not be formed between the multifunction electrode and the semiconductor layer. Accordingly, the TFT may operate only at the time of inputting the signal to the gate electrode and a leakage current due to the multifunctional electrode positioned on the upper portion of the semiconductor layer may not occur.

In the exemplary embodiment of the present invention as described above, as an electrode layer corresponding to a general pixel electrode has functions of a drain electrode and a light shielding layer, the electrode layer is called the multifunction electrode 170.

Hereinafter, a method of manufacturing the reflective type display device according to the exemplary embodiment of the present invention, including the multifunction electrode as described above, will be described in detail.

First, in order to manufacture the reflective type display device according to the exemplary embodiment of the present invention, a plurality of the gate lines G are formed at a predetermined interval on a substrate 110 as illustrated in FIG. 3.

In this case, a gate electrode 120 may be formed together with the formation of the gate lines G in order to form the TFT, and in this case, the gate electrode 120 and the gate lines G are formed to be connected to each other so as to supply the gate electrode 120 with a gate voltage.

When the gate lines G and the gate electrode 120 are formed, a first insulating layer 130 may be formed on an entire surface of the substrate 110 on which the gate lines and the gate electrode are formed.

Thereafter, according to a first exemplary embodiment, the semiconductor layer 140 may be formed on the first insulating layer 130, and the data lines D and a source electrode 150 may be simultaneously formed.

More specifically, as illustrated in FIGS. 3 and 4, after forming the semiconductor layer 140 above the gate electrode 120 with the first gate insulating layer 130 interposed therebetween in such a manner that the semiconductor layer 140 and the gate electrode 120 are planarly overlapped with each other, the plurality of data lines D may be formed at a predetermined interval such that they intersect with the gate lines G to define unit pixel regions. In this case, the plurality of data lines D may be formed together with the source electrode 150, and one side of the source electrode may be connected to the data line D in order to receive the data signal from the data line D and the other side thereof may be formed to be overlapped with a portion of the semiconductor layer.

Meanwhile, according to a second exemplary embodiment, after the data lines D and the source electrode 150 are formed first as illustrated in FIG. 5, the semiconductor layer 140 may be formed to be overlapped with a portion of the source electrode.

According to the related art, as illustrated in FIG. 2, when a source electrode is formed, a drain electrode may be formed to be spaced apart from the source electrode by a predetermined distance. However, in the reflective type display device according to the exemplary embodiment of the present invention as described above, since the multifunctional electrode 170 may function as the drain electrode receiving an electrical signal from the source electrode, a separate drain electrode may not be formed unlike the case of the related art.

A second insulating layer 160 may be formed on a resultant product on which all of the data lines D, the semiconductor layer 140, and the source electrode 150 are formed. The second insulating layer may be an organic insulating layer and in order to improve insulating characteristics of the organic insulating layer, a passivation layer (not shown), an inorganic insulating layer may be further formed, prior to the formation of the second insulating layer 160.

Then, a portion of the second insulating layer may be etched to form a contact hole H2. The contact hole H2 may be a constitution for electrically connecting the multifunction electrode 170 to the semiconductor layer. Thus, the second insulating layer may be etched so as to expose a portion of the semiconductor layer, thereby forming the contact hole H2. In the case that a passivation layer is formed below the second insulating layer 160, the passivation layer may be etched together with the second insulating layer so as to expose the semiconductor layer. In addition, in some cases, when the passivation layer is formed, patterning may be performed in such a manner as not to form the passivation layer in a portion in which the contact hole H2 will be formed.

When the contact hole H2 is formed as described above, a conductive material may be stacked on the second insulating layer to thereby form the multifunction electrode 170. In this case, the multifunction electrode 170 may be directly connected to the semiconductor layer 140 through the contact hole H2.

A conductive material forming the multifunction electrode may be an indium tin oxide (ITO) or indium zinc oxide (IZO) in the same manner to that of a pixel electrode according to the related art. However, since the multifunction electrode according to the exemplary embodiment of the present invention may have functions of a drain electrode, in the case that the multifunction electrode is outwardly exposed, the case is identical to the case in which the drain electrode is outwardly exposed. Thus, the multifunction electrode may be formed of a corrosion-resistant alloy such as a molybdenum alloy or a titanium alloy having a high degree of resistance to corrosion.

Since the multifunction electrode 170 is directly connected to the semiconductor layer as described above, a back-channel may not be formed, whereby a leakage current may not be generated. Thus, the multifunction electrode 170 may have a formation area D2 thereof greater than a formation area D1 of the pixel electrode according to the related art illustrated in FIG. 2. Thus, the reflective type display device according to an exemplary embodiment of the present disclosure may have effects of increasing a fill-factor.

In addition, since the multifunction electrode 170 may be formed to cover the entirety of the upper portion of the semiconductor layer, the activation of the semiconductor layer due to external light may be blocked without a separate light shielding layer 7. Thus, the multifunction electrode 170 according to the exemplary embodiment of the present invention may serve as a light shielding layer.

In addition, the multifunction electrode 170 may serve as a drain electrode receiving a data signal from the source electrode.

Thus, processes of forming a drain electrode, a pixel electrode, and a light shielding layer according to the related art may be replaced with a single process of forming a multifunction electrode, such that a manufacturing process of the reflective type display device according to the exemplary embodiment of the present invention may be simplified and a manufacturing cost thereof may be reduced.

As set forth above, according to exemplary embodiments of the present invention, a reflective type display device in which a fill-factor is improved due to the expansion of a pixel electrode and a leakage current is not generated, by including a multifunctional electrode serving as the pixel electrode, a drain, and a light shielding layer may be provided. Further, the reflective type display device may allow for the simplification of a manufacturing process and a significant decrease in a manufacturing cost thereof.

What is claimed is:

1. A reflective type display device having a lower substrate on which a plurality of gate lines and a plurality of data lines are arranged to intersect each other in order to form a plurality of unit pixel regions and an upper substrate, the reflective type display device comprising:
in each of the unit pixel regions of the lower substrate,
a gate electrode connected to one of the gate lines;
a first insulating layer formed on an entire surface of the lower substrate on which the gate lines and the gate electrode are formed;
a semiconductor layer planarly overlapped with the gate electrode, with the first insulating layer interposed therebetween;
a source electrode having one side connected to one of the data lines and the other side formed to be overlapped with a portion of the semiconductor layer;
a second insulating layer formed on the entire surface of the lower substrate on which the semiconductor layer and the source electrode are formed;
a contact hole formed by removing a portion of the second insulating layer so as to expose a partial region of the semiconductor layer; and
a multifunction electrode formed on the second insulating layer and directly connected to the semiconductor layer through the contact hole.

2. The reflective type display device according to claim 1, wherein the multifunction electrode is formed to cover the entirety of an upper portion of the semiconductor layer.

3. The reflective type display device according to claim 1, wherein the other side of the source electrode is positioned between the first insulating layer and the semiconductor layer.

4. The reflective type display device according to claim 1 wherein the other side of the source electrode is positioned between the semiconductor layer and the second insulating layer.

5. The reflective type display device according to claim 1, wherein the multifunction electrode is formed of a corrosion resistant alloy.

6. The reflective type display device according to claim 5, wherein the corrosion resistant alloy is a molybdenum alloy or a titanium alloy.

7. The reflective type display device according to claim 1, further comprising: a passivation layer disposed below the second insulating layer.

8. A method of manufacturing a reflective type display device having a lower substrate on which a plurality of gate lines and a plurality of data lines are arranged to intersect each other in order to form a plurality of unit pixel regions and an upper substrate, the method comprising:
forming the gate lines and a gate electrode on the lower substrate;
forming a first insulating layer on the lower substrate on which the gate lines and the gate electrode are formed;
forming a semiconductor layer, the data lines, and a source electrode on the first insulating layer, the semiconductor layer being planarly overlapped with the gate electrode, and the source electrode being connected to one of the data lines and being partially overlapped with the semiconductor layer;
forming a second insulating layer including a contact hole so as to expose a partial region of the semiconductor layer on the lower substrate on which the semiconductor layer, the data lines, and the source electrode are formed; and
forming a multifunction electrode on the second insulating layer to be directly connected to the semiconductor layer through the contact hole.

9. The method according to claim 8, wherein the multifunction electrode is formed to cover the entirety of an upper portion of the semiconductor layer.

10. The method according to claim 8, wherein the source electrode has one side connected to one of the data lines and the other side positioned between the first insulating layer and the semiconductor layer.

11. The method according to claim 8, wherein the source electrode has one side connected to one of the data lines and the other side positioned between the semiconductor layer and the second insulating layer.

12. The method according to claim 8, wherein the multifunction electrode is formed of a corrosion resistant alloy.

13. The method according to claim 12, wherein the corrosion resistant alloy is a molybdenum alloy or a titanium alloy.

14. The method according to claim 8, further comprising: forming a passivation layer on the upper portion of the lower substrate on which the data lines, the semiconductor layer, and the source electrode are formed, prior to the formation of the second insulating layer.
